(19) United States
(12) Patent Application Publication
(10) Pub. No.: US 2009/0315069 A1
(43) Pub. Date: Dec. 24, 2009

(54) THIN GALLIUM NITRIDE LIGHT EMITTING DIODE DEVICE

(75) Inventors: Jae Seung LEE, Daejeon (KR); Bu Gon SHIN, Busan (KR); Min Ho CHOI, Pohang-si (KR); Jong Hoon KANG, Seoul (KR); Min A YU, Daejeon (KR); Byung Du OH, Seoul (KR)

Correspondence Address: ROBERT E. BUSHNELL & LAW FIRM, 2029 K STREET NW, SUITE 600, WASHINGTON, DC, 20006-1004, US

(73) Assignee: HANBEAM CO., LTD., Suwon (KR)

(21) Appl. No.: 12/550,057

(22) Filed: Aug. 28, 2009

Related U.S. Application Data
(62) Division of application No. 11/298,505, filed on Dec. 12, 2005.
Application No. 11/298,505 is a continuation-in-part of application No. 11/175,182, filed on Jul. 7, 2005, now abandoned.

(30) Foreign Application Priority Data
Dec. 13, 2004 (KR) 10-2004-0105063
Sep. 16, 2005 (KR) 10-2005-0086951
Sep. 16, 2005 (KR) 10-2005-0086953
Sep. 23, 2005 (KR) 10-2005-0088664

(51) Int. Cl. H01L 33/00

(52) U.S. Cl. 257/103; 438/33; 257/76; 438/46; 257/E33.025; 257/E33.055; 257/E33.066

(57) ABSTRACT

Disclosed is a light emitting diode (LED) device that comprises a crystal structure of a sapphire substrate-free gallium nitride (GaN) LED, wherein the crystal structure is mounted on a first surface of a sub-mount substrate in the form of a unit chip, and the first surface of the sub-mount substrate has a surface area greater than the surface area of a region in which the unit chip is bonded. Preforms for manufacturing the LED device and a method for manufacturing the LED device are also disclosed. The sapphire substrate, on which the crystal structure of the light emitting diode has grown, is processed into a unit chip before being removed. Thus, any crack in the crystal structure of the light emitting diode that may occur during the removal of the sapphire substrate can be prevented. Therefore, a thin light emitting diode device can be manufactured in a mass production system.

This application is a continuation-in-part claiming priority to U.S. patent application Ser. No. 11/175,182, filed Jul. 7, 2005, which is based on Korean Application No. 10-2004-105063, filed Dec. 13, 2005 in Korean Industrial Property Office, the content of which is incorporated hereinto by reference.

Further, this application claims the benefit of Korean Application No. 10-2005-86951, filed Sep. 16, 2005, Korean Application No. 10-2005-86953, filed Sep. 16, 2005 and Korean Application No. 10-2005-88664, filed Sep. 23, 2005, in Korean Industrial Property Office, which are hereby incorporated by reference in their entirety for all purposes as if fully set forth herein.

### TECHNICAL FIELD

The present invention relates to a novel thin light emitting diode device, which has improved light emitting efficiency and heat dissipation rate, and preforms and a method for manufacturing the same.

### BACKGROUND ART

In general, a light emitting diode (LED) device is a semiconductor device that generates light by causing electric current to flow through a PN junction in the forward direction.

LEDs using a semiconductor have been the focus of attention in the field of applied lighting equipments of next generation, due to their advantages of having high efficiency in converting electric energy to light energy, a long lifespan of more than 5 to 10 years, and high cost efficiency resulting from reduced maintenance cost and low power consumption.

Sapphire substrates are widely used to grow the GaN-based compound semiconductors for use in the manufacture of LEDs. Sapphire substrates are electric insulators, constructed so that the anodes and cathodes of LEDs are formed on the front surface of a wafer.

In general, a top emission type GaN light emitting diode is widely used in low-output applications. As shown in FIG. 1a, a GaN LED is manufactured by a process comprising the steps of: placing a sapphire substrate 10, on which a crystal structure has grown, on a lead frame 20, and then connecting two electrodes 11 and 12 with the top portion of the sapphire substrate 10. At this time, in order to improve the heat dissipation rate, the sapphire substrate is bonded to the lead frame after reducing its thickness to about 100 micron or less.

However, thermal conductivity of a sapphire substrate is about 50 W/mK. Therefore, even if the thickness is reduced to about 100 micron, it is difficult to obtain the desired heat dissipation property with the arrangement as shown in FIG. 1a, due to the significantly high thermal resistance.

Thus, it is the current trend to employ a flip-chip bonding technique as shown in FIG. 1b to further improve the heat dissipation property of a high output GaN light emitting diode. In the flip-chip bonding technique, a chip with an LED structure, which has grown on the sapphire substrate, is flip over upside down, and is bonded to a sub-mount substrate 30, such as a silicon wafer or an AlN ceramic substrate having excellent thermal conductivity (about 150 W/mK or 180 W/mK). In this case, because the heat dissipation is made through the sub-mount substrate, the heat dissipation rate is improved compared to the heat dissipation made through the sapphire substrate. However, the improvement is not so satisfactory.

With regard to the above-mentioned problem, a thin film type GaN LED without a sapphire substrate has been suggested recently. A typical method for manufacturing an LED by removing the sapphire substrate comprises removing the sapphire substrate from the crystal structure of the LED by way of laser lift-off technique before packaging. This method is known to provide the highest heat dissipation rate.

Furthermore, unlike the flip-chip bonding technique, such removal of the sapphire substrate by way of lift-off technique does not require a delicate flip-chip bonding process, and is comprised of simple processing steps if the problem related with the removal of the sapphire substrate is solved. Also, the sapphire substrate-free thin film type LED shows superior properties to the LED manufactured by the flip-chip bonding technique, because the former LED has a light emitting area of about 90% of the size of chips, while the latter LED has a light emitting area of about 60% of the size of chips.

Despite the aforementioned advantages, however, the conventional laser lift-off technique widely used for removing sapphire substrates is not yet applicable to mass production. This is because the conventional laser lift-off technique causes structural crack in the LED crystal due to the stress present between the sapphire substrate and the crystal structure of the LED upon the irradiation of laser, and thus provides significantly low yield in spite of excellent heat dissipation property.

Therefore, there is an imminent need for a method for manufacturing a sapphire substrate-free thin film type GaN light emitting diode, having excellent light emission efficiency and heat dissipation efficiency, in mass quantity.

### DISCLOSURE OF THE INVENTION

According to the conventional laser lift-off technique, the entire sapphire substrate (e.g. a 2 inch-sized sapphire substrate), on which the crystal structure of the LED has grown, is bonded to a sub-mount substrate having the same size as the sapphire substrate, and then laser is irradiated toward the sapphire substrate to remove it from the crystal structure of the GaN LED. Then, the sub-mount substrate and the crystal structure of the LED are subjected to dicing or scribing/breaking treatment, so that they are cut into unit LED chips, and the unit chips are attached to the lead frame (see FIG. 2).

However, in the conventional laser lift-off technique, only a small area of at most 3 cm² can be irradiated with one shot of a laser beam. Therefore, in order to remove the sapphire substrate totally, the whole area of the conventional 2-inch sapphire substrate should be irradiated with laser beams at least several tens of times, while moving the laser beams sequentially. Meanwhile, stress present between the sapphire substrate and the crystal structure of the LED causes crack at the edge portions of each region-irradiated with one shot of a laser beam in the crystal structure of the LED. Because of such crack, the yield obtained from the conventional laser lift-off technique is considerably low in spite of excellent light emission efficiency and heat dissipation property. Hence, this technique is not yet applicable to mass production.

The present inventors have recognized that crack arises in the crystal structure of a light emitting diode device at the edge portions of each region irradiated with laser beams during laser irradiation of the whole areas of a sapphire wafer. To solve this, we adopted a method that comprises: forming unit chips from a sapphire substrate, on which the crystal structure of the LED has grown, before removing the sapphire substrate by way of the laser irradiation thereto; bonding at least one unit chip to a sub-mount substrate; and removing the sapphire substrate. By doing so, the sapphire substrate in the form of a unit LED chip smaller than the size of a region irradiated with laser beams can be separated by one shot of laser irradiation, resulting in the production of a thin LED device that causes no crack in its crystal structure.

Herein, at least two unit LED chips, spaced apart from each other, are bonded to the sub-mount substrate, and then the sub-mount substrate is cut in a position between the two adjacent unit chips. Otherwise, only one unit chip is attached to a sub-mount substrate that is greater than the size of the unit chip to be bonded thereto. By doing so, a novel structure having a surface of the sub-mount substrate, extending from the circumference of a region in which the unit chip is bonded, can be obtained. Further, if the sub-mount substrate having a surface metal layer on its first surface is used, the metal layer is exposed on the portion extending from the region in which the unit chip is bonded, then a novel thin light emitting diode device is provided, wherein the exposed metal layer is subjected to wire bonding, or serves as a reflection layer that reflects the light emitted from the lateral surfaces of the LED, so that the light can be reflected to the exterior (see FIG. 3).

Therefore, according to an aspect of the present invention, there is provided a light emitting diode (LED) device that comprises the crystal structure of a sapphire substrate-free GaN LED, wherein the crystal structure is mounted on a first surface of a sub-mount substrate in the form of a unit chip, and the first surface of the sub-mount substrate has a surface area greater than the surface area of a region in which the unit chip is bonded.

In a preferred embodiment of the present invention, a metal layer may be formed on the first surface of the sub-mount substrate, wherein the metal layer may be exposed to the exterior on the sub-mount substrate by extending from the circumference of the region in which the unit chip is bonded. Preferably, the above exposed metal layer serves as a reflection layer with a high light reflection ratio. Additionally, wire bonding may be formed on the above exposed metal layer.

According to another aspect of the present invention, there is provided a method for manufacturing a light emitting diode device by allowing the crystal structure of a GaN LED to grow on a sapphire substrate, the method comprising the steps of: splitting the sapphire substrate, on which the crystal structure of the LED has grown, into a unit chip; and removing the sapphire substrate from the unit chip.

In a preferred embodiment of the present invention, at least one unit chip is bonded to a sub-mount substrate, followed by removal of the sapphire substrate. When at least two unit chips are bonded to the sub-mount substrate, the above method may further comprises a step of cutting the sub-mount substrate in a position between two adjacent unit chips, so that the sub-mount substrate can be provided with one or at least two unit chips after the removal of the sapphire substrate.

According to the above method of the present invention, the GaN LED device according to the present invention can be obtained. Additionally, during the progress of the method, a first preform, a second preform and a third preform as described hereinafter may be provided, and such preforms may be commercialized (see FIG. 3).

Therefore, according to still another aspect of the present invention, there is provided a first preform for manufacturing a light emitting diode device, which comprises a sapphire substrate, on which the crystal structure of a GaN LED has grown, mounted on a sub-mount substrate in the form of at least two unit chips.

According to still another aspect of the present invention, there is provided a second preform for manufacturing a light emitting diode device, which is obtained by removing the sapphire substrate from the first preform that comprises a sapphire substrate, on which the crystal structure of a GaN LED has grown, mounted on a sub-mount substrate in the form of at least two unit chips.

According to yet another aspect of the present invention, there is provided a third preform for manufacturing a light emitting diode device, which is obtained by removing the sapphire substrate from the first preform that comprises a sapphire substrate, on which the crystal structure of a GaN LED has grown, mounted on a sub-mount substrate in the form of at least two unit chips, and by cutting the sub-mount substrate in a position between two adjacent unit chips.

In a preferred embodiment of the preforms according to the present invention, a metal layer may be formed on the first surface of the sub-mount substrate, on which the sapphire substrate, comprising the grown crystal structure of a GaN LED, is mounted in the form of unit chips.

### BRIEF DESCRIPTION OF THE DRAWINGS

The foregoing and other objects, features and advantages of the present invention will become more apparent from the following detailed description when taken in conjunction with the accompanying drawings in which:

FIGS. 1a and 1b are schematic views showing the structure of a top emission type gallium nitride (GaN) light emitting diode (LED) and that of a flip-chip type GaN LED;

FIG. 2 is a flow chart showing the process for manufacturing the unit chip of a thin GaN LED according to the prior art;

FIG. 3 is a flow chart showing the process for manufacturing a unit chip of a thin GaN LED according to the present invention;

FIG. 4 is a schematic view showing the unit chip of a thin GaN LED according to a preferred embodiment of the present invention;

FIG. 5 is a schematic view of how to define the portion to be separated as a unit chip via dry etching in a sapphire substrate, on which the LED crystal structure is grown;

FIGS. 6a and 6b shows the n-ohmic contact metal patterns for a small chip having one wire bonding and for a large chip having four wire bondings, respectively;

FIGS. 7a and 7b are electrode wiring diagrams in the case of n-type ohmic contact metals, wherein only one wire bonding is formed in a large chip and the ohmic contact metals are used as electrode wires;

FIG. 8 is a schematic cross-sectional view illustrating the structure of surface roughness formed on an n-type GaN layer; and

FIGS. 9a and 9b are schematic sectional views of GaN LEDs manufactured by way of the laser lift-off technique according to the present invention, wherein each LED uses a metal substrate or silicon substrate, and a ceramic or silicon substrate as a sub-mount substrate, respectively.

### BEST MODE FOR CARRYING OUT THE INVENTION

Reference will now be made in detail to the preferred embodiments of the present invention.

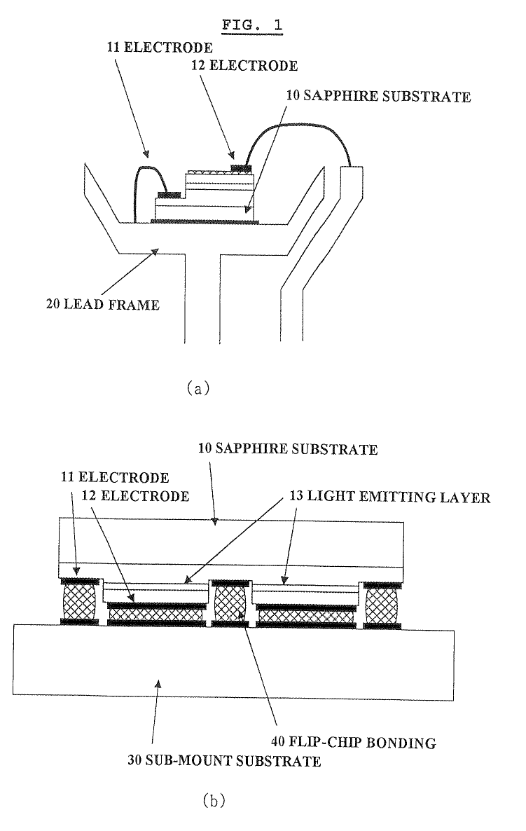

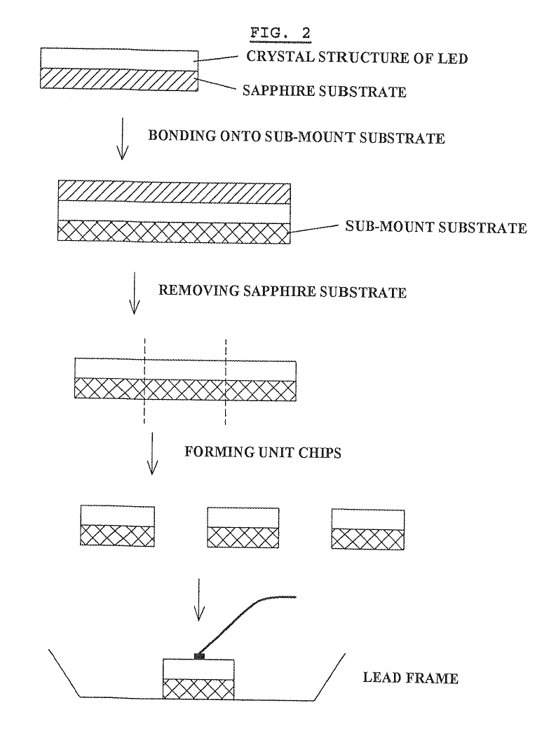

FIG. 2 is a flow chart showing the process for manufacturing a unit chip of a thin gallium nitride (GaN) LED according to the prior art.

As shown in FIG. 2, the process for manufacturing a light emitting diode comprises the steps of: allowing the crystal structure of a GaN LED to grow on a sapphire substrate; mounting the sapphire substrate, on which the crystal structure has grown, onto a sub-mount substrate; removing the sapphire substrate from the resultant structure; splitting the resultant structure into a unit chip; and mounting the unit chip onto a lead frame.

Herein, when the sapphire substrate is removed locally and gradually from the crystal structure of the LED via a physical and/or chemical means (e.g. laser lift-off), in the presence of the stress between the crystal structure of the LED and the sapphire substrate, a non-uniform stress distribution is formed between the crystal structure of the LED and the sapphire substrate due to the removed portions different from non-removed portions, resulting in crack of the crystal structure.

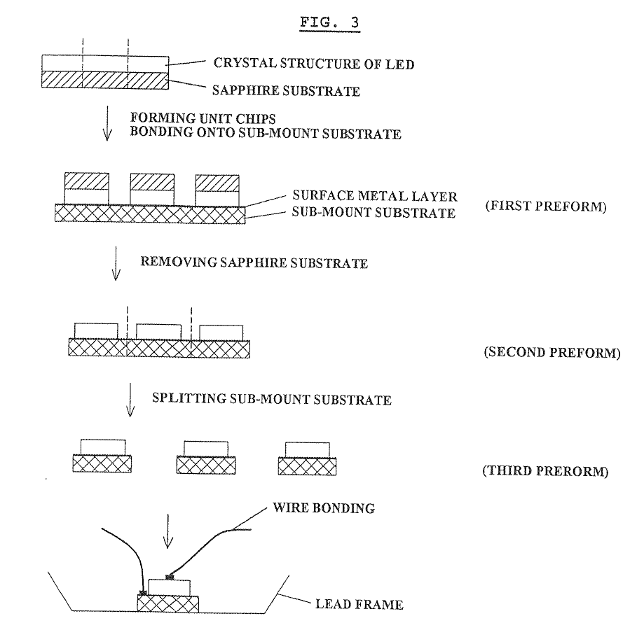

FIG. 3 is a flow chart showing the process for manufacturing a unit chip of a thin GaN LED according to the present invention.

In order to prevent such crack of the crystal structure, as shown in FIG. 3, the present invention is characterized in that the sapphire substrate, on which the crystal structure of a GaN LED has grown, is preliminarily split into a unit chip having such a size as to minimize the non-uniform stress distribution caused by the removal of the sapphire substrate, and then, the sapphire substrate is removed from the unit chip. Due to the above characteristic of the present invention, the above-mentioned problem related with the crack of the crystal structure can be solved, so that a thin film type (i.e. sapphire substrate-free) light emitting diode device can be obtained.

Herein, at least one unit chip may be bonded to the sub-mount substrate, and then the sapphire substrate may be removed. In this case, at least two unit chips, spaced apart from each other, are bonded to the sub-mount substrate, and then the sub-mount substrate is cut in a position between two adjacent unit chips. Otherwise, only one unit chip is bonded to the sub-mount substrate having a size greater than the size of the region in which the unit chip is bonded, so as to manufacture a light emitting diode device. By doing so, it is possible to obtain a characteristic structure, wherein the surface of the sub-mount substrate extends from the circumference of the region in which the unit chip is bonded. In this case, such extended surface of the sub-mount substrate may be subjected to wire bonding, or may form a reflection layer that reflects the light emitted from the lateral surfaces of the LED so that the light can be reflected to the exterior (see FIG. 4).

Therefore, according to another preferred embodiment of the present invention, the sub-mount substrate comprises a metal layer formed on the first surface thereof, and at least one unit chip is bonded to the first surface, wherein the metal layer may be in electric contact with the crystal structure of the LED, and/or may serve as a reflection layer.

More particularly, the metal layer is provided preferably by using an adequate metallic material, so that the metal layer may be in electric contact with the crystal structure of the LED, and/or may serve as a reflection layer that reflects the light emitted from the lateral surfaces of the LED to cause the light to be reflected to the exterior.

When the metal layer is not amenable to wire bonding, it is preferable to form an n-ohmic contact metal on the metal layer in the position to be subjected to wire bonding upon the formation of the n-ohmic contact metal on the surface of the crystal structure of the LED. In general, the ohmic contact metal includes a gold (Au) layer at the top thereof in order to decrease the electric resistance of the ohmic contact metal layer as well as to perform wire bonding. Therefore, when the n-ohmic contact metal is formed on the metal layer in the position to be subjected to wire bonding upon the formation of the n-ohmic metal contact on the surface of the LED, the subsequent wire bonding step may be facilitated.

Meanwhile, in the LED device according to the present invention, the metal layer exposed on the sub-mount substrate surface extending from the region in which the unit chip is bonded, may be damaged by laser, reagents, or the like, used in various steps for manufacturing the LED (for example a step of removing the sapphire substrate by way of laser, a step of forming surface roughness on the n-type GaN surface exposed after the removal of the sapphire substrate in order to increase the light extraction efficiency, or the like). Therefore, it is preferable that the metal layer has excellent resistance against lasers and excellent chemical resistance against the reagents.

Under these circumstances, it is preferable to form a metal layer, which has excellent chemical resistance, high resistance against lasers, high reflection ratio to the visible light and good electroconductivity, on the surface of the sub-mount substrate. Particular examples of the metal include Pt, Rh, Ru, Au and their alloys with other metals.

The thin GaN LED device according to the present invention can be manufactured by a process generally known to one skilled in the art, except that a GaN LED comprising a crystal structure, which has grown on a sapphire substrate, is split into a unit chip before the sapphire substrate is removed from the crystal structure, the unit chip is bonded to a sub-mount substrate, and then the sapphire substrate is removed. Each step that may be performed optionally is as described below, wherein the order of each step may be changed.

(1) Step of Growing Light Emitting Diode Section on Sapphire Substrate

A crystal structure of a GaN light emitting diode, such as an n-type layer, a p-type layer or an active layer, is allowed to grow on a sapphire substrate, by way of the Metal Organic Chemical Vapor Deposition (MOCVD) method or the Molecular Beam Epitaxy (MBE) method, so as to form a light emitting diode section. In particular, the n-type layer, the p-type layer or the active layer may be formed by using a GaN compound generally known to one skilled in the art, such as GaN, InGaN, AlGaN, or AlInGaN. The p-type layer and the n-type layer may not be doped with a p-type dopant and an n-type dopant, respectively. However, they are preferably doped with the dopants. Additionally, the active layer may have a single quantum well (SQW) structure or a multiple quantum well (MQW) structure. The crystal structure may further include another buffer layer, besides the n-type layer, the p-type layer or the active layer. It is possible to provide various light emitting diodes ranging from a short wavelength to a long wavelength by controlling the composition of the GaN compound. Therefore, the present invention is not limited to blue LEDs (wavelength: 460 nm) based on nitrides but is applied to all kinds of light emitting diodes.

(2) Step of Forming P-Type Ohmic Contact

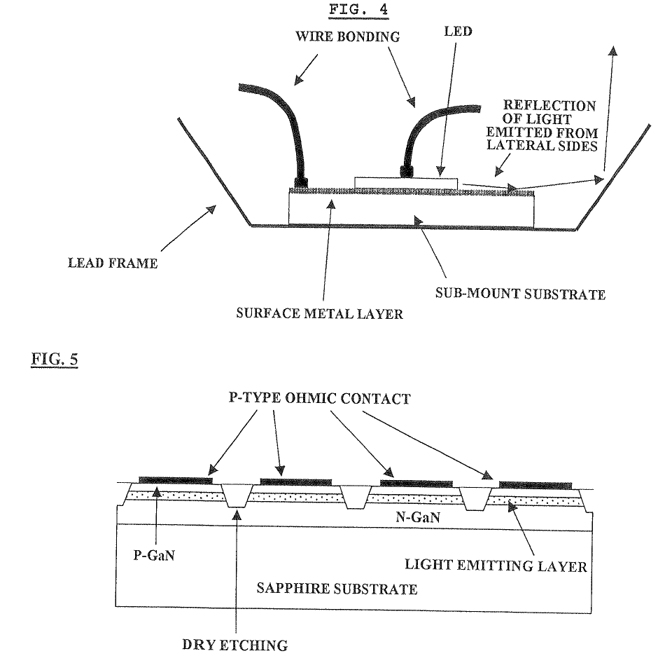

Optionally, a step of forming a p-type ohmic contact may be performed (see FIG. 5).

A wafer, having the crystal structure of a GaN LED that has grown on the sapphire substrate was washed initially, and a single metal or alloy, such as Ni, Au, Pt, Ru or ITO was deposited on the p-type surface (e.g. p-type GaN) present on the top of the wafer in a single layer or in multiple layers via vacuum deposition, thereby forming a p-type ohmic contact metal. Next, thermal annealing is carried out to finish the p-type ohmic contact. Herein, an additional metal layer such as Ag, Al, Cr or Rh may be used for the purpose of light reflection. Also, if necessary, another metal layer may be added to the top of the p-type ohmic contact metal, so as to improve the bonding to a substrate such as a sub-mount substrate.

(3) Step of Dry Etching

Optionally, a step of dry etching for defining a position in which the sapphire substrate is split into a unit chip may be performed (see FIG. 5).

The subsequent scribing and breaking step for the formation of a unit chip causes crack (e.g. zigzag-shaped crack) in the crystal at the lateral surface of the broken edge portions of the unit chip. Such crack at the edge portions arise current leakage during the operation of the LED device, thereby causing the problem related with long-term reliability.

Therefore, it is preferable that regions for the light emission are defined via a dry etching step, so that current flow toward the cleaved sites can be interrupted.

For example, the dry etching step is performed by dry etching the portions to be present as edges of a unit chip until the light emitting active layer is exposed, or preferably until the n-type GaN layer is exposed, so that flat lateral surfaces are formed.

(4) Step of Polishing Surface of Sapphire Substrate

Optionally, a step of polishing the surface of the sapphire substrate may be performed.

In general, the crystal structure of an LED is grown on the sapphire substrate, which has a thickness of approximately 430 microns. To be processed as a device, the sapphire substrate is thinned to have a thickness of about 80-100 microns by means of the lapping/polishing process.

It is the reason to perform such thinning and polishing treatment of the sapphire substrate that the treatment facilitates the subsequent scribing/breaking step as well as the transmission of laser beams through the sapphire substrate.

(5) Step of Forming Unit Chips

In the step of splitting a sapphire substrate comprising the grown crystal structure of an LED into unit chips, the scribing/breaking process is preferably used. However, other processes may be used.

In general, the term “scribing” refers to drawing of lines on the surface of a wafer with a laser or a diamond tip having a sharp end and excellent strength, while the term “breaking” refers to cutting of the wafer with an impact along the line drawn by means of scribing.

Preferably, a unit chip is in the size of a chip to be processed into a final LED lamp, which cannot be reduced in the following steps any more. In the case of a high-output LED, the size is preferably about 1×1˜5×5 mm². In the case of a medium- to low-output LED, the size is preferably about 0.2×0.2˜1×1 mm².

(6) Step of Bonding to Sub-Mount Substrate

Optionally, the resultant structure obtained from the preceding steps may be bonded to the sub-mount substrate. Herein, the sub-mount substrate may further comprise a metal layer on the surface to be bonded. The sub-mount substrate may be comprised of a conductive material or a non-conductive material. In the case of a high-output LED, a sub-mount substrate, such as a metal or silicon wafer, is preferably used to improve the heat dissipation efficiency.

The sub-mount substrate may comprise materials such as CuW, metals including Al and Cu, Si wafer, AlN ceramics, Al₂O₃ ceramics, or the like.

As the metal layer formed on the surface of the sub-mount substrate, metals such as Pt, Rh, Ru and Au, and alloys thereof may be used. Preferably, the metal has excellent chemical resistance, strong resistance against lasers, good adhesive properties in regards to the adhesives as described below, a high reflection ratio to the visible light, and electroconductivity.

The sub-mount substrate is amenable to mass production to a higher degree, as its size increases to become greater than 1 inch. However, the larger the size becomes thicker thickness is required in order to prevent its breakage or bending in the course of treatment. Thus, an increase in the thickness of the sub-mount substrate is disadvantageous for heat dissipation property. In consideration of the heat dissipation characteristics as well as of mass productivity, it is preferable to select the sub-mount substrate with a size ranging from about 1 to 6 inches.

Preferably, the adhesives that may be used in the step of bonding to the sub-mount substrate supplies electric current to the LED therethrough and discharges the heat generated from the LED with ease. Particularly, a material with a low melting point, such as AuSn, AgSn, PbSn, Sn, Ag powder or silver paste, or other metals that can be adhered at a low temperature of 300° C. or less, for example, combination of In and Pd.

For example, the unit chip having the polished sapphire substrate is turned over so as to cause the sapphire substrate to be present on the top of the sub-mount substrate. Then, the surface of the p-type ohmic contact metal of the LED is bonded to the sub-mount substrate by using a metallic bonding material with excellent heat dissipation capability.

When at least two unit chips are bonded to a single sub-mount substrate, the unit chips are preferably arranged periodically at adequate intervals of approximately several hundreds of microns between two adjacent chips, in consideration of the subsequent dicing step and wire bonding step of the sub-mount substrate. Additionally, it is preferable that the interval between two adjacent chips is controlled so as to prevent the unit chips from being placed over the edges of the region in which laser beams are irradiated subsequently for removing the sapphire substrate.

In the bonding step, a device such as Dibonder™ may be employed. In consideration of the characteristics of the device, the sub-mount substrate preferably has a pattern in a position, where the unit chip is bonded. Preferably, the pattern represents the cutting position, where the sub-mount substrate is split subsequently into unit sub-mount substrates. However, at least two unit LED chips may be bonded to a single unit sub-mount substrate. Therefore, in the latter case, an additional pattern is preferably formed in a position other than the above cutting position of the sub-mount substrate. Preferably, patterning is performed after the formation of the metal layer on the sub-mount substrate. However, patterning may be also performed before the formation of the metal layer.

Also, it is preferable to draw lines in such a manner that the interval between two adjacent unit LED chips becomes a constant distance of several hundreds of microns as measured along the vertical and horizontal lines in a square.

Then, the unit LED chips are bonded to the sub-mount substrate by recognizing the lines drawn as a pattern during the bonding step. To draw the lines, a dicing process or a scribing process using a laser or diamond tip may be utilized. The lines have such a depth as to be recognized by the Dibonder or the naked eyes, but are not limited thereto. To prevent the sub-mount substrate being broken unintentionally during the subsequent steps, the dicing or scribing process is preferably performed to a depth enough to maintain a certain level of physical strength.

(7) Step of Removing Sapphire Substrate

Non-limiting examples of the method for removing the sapphire substrate from the unit chip include irradiation of laser beams, such as eximer laser.

When the sapphire substrate is removed from each unit chip by irradiating the chip with laser at the surface of the sapphire substrate, one or more sapphire substrates are removed from one or more chips at the same time by one-shot of the laser beam. Therefore, no crack occurs in the crystal structure of each unit chip. Herein, it is important to prevent the unit chip from being placed over the edges of the region subjected to laser irradiation.

Preferably, the wavelength of the laser beam ranges from 200 nm to 365 nm, which is higher than the energy gap of gallium nitride.

The laser beams transmitted through the sapphire substrate are absorbed by gallium nitride to cause the gallium nitride (GaN) present in the interface between the sapphire substrate and GaN to decompose into gallium metal and nitrogen gas. Therefore, the sapphire substrate is separated from the crystal structure of the LED.

According to the present invention, any other method than the above method of laser irradiation to the sapphire substrate may be used to remove the sapphire substrate.

For example, when growing the crystal structure of a light emitting diode on a sapphire substrate, a GaN buffer layer is generally grown at the initial time under low temperature. When using the additional metal buffer layer, it is possible to remove the sapphire substrate by using an acid capable of dissolving the metal, instead of the laser irradiation.

(8) Step of Forming N-Type Ohmic Contact Metal

If necessary, an n-type ohmic contact metal may be formed on the n-type surface (e.g. n-type GaN) exposed after the removal of the sapphire substrate, by using metals such as Ti, Cr, Al, Sn, Ni and Au in combination via vacuum deposition.

Preferably, the n-type GaN surface undergoes a polishing step or a dry/wet etching step before forming the n-type ohmic contact metal.

Metal gallium generated upon the decomposition of GaN still exists on the surface of GaN, which has been exposed after the removal of the sapphire substrate. The metal gallium layer of such surface lessens the quantity of light emitted from the LED. Hence, the metal gallium layer is removed by means of hydrochloric acid. If necessary thereafter, undoped-GaN layer is etched by means of dry or wet etching treatment so as to expose an n⁺-GaN layer. Then, Metal (e.g. Ti/Al based metal) for the formation of the n-ohmic contact metal is deposited via vacuum deposition.

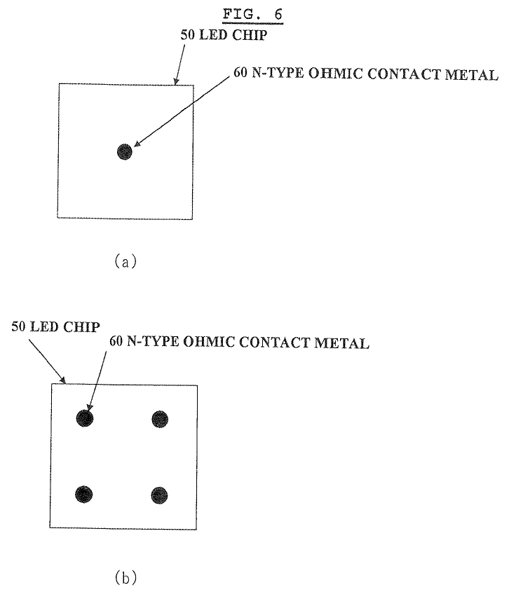

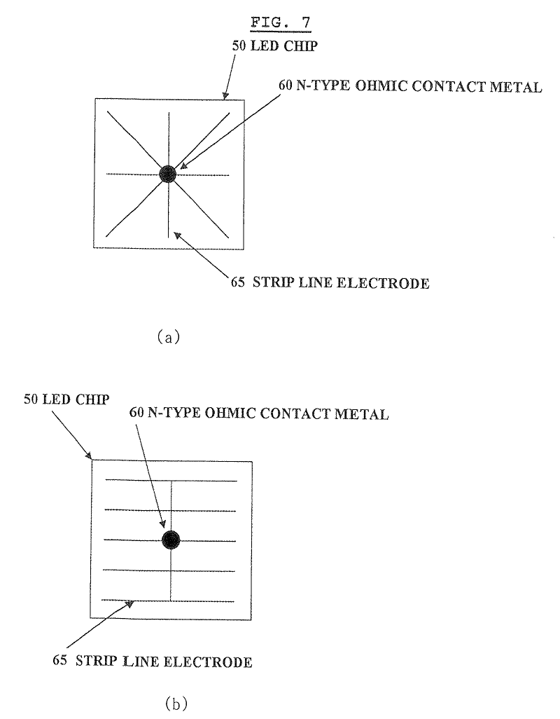

The n-type ohmic contact structure according to the present invention will now be described by reference to FIGS. 6a and 6b. As shown in FIGS. 6a and 6b, the n-type ohmic contact metal can be formed only at a position where Au wire bonding of the LED chip 50 will be performed. Otherwise, as shown in FIGS. 7a and 7b, it is possible to decrease the number of wire bondings by forming the n-type ohmic contact metal 60 at a position where the wire bonding will be performed, and by further forming the strip line electrode 65 in addition. The ohmic contact point is a position, at which wire bonding is to be performed in the next step, i.e. a location to be connected to a cathode after performing the wire bonding. Therefore, it is different from the ohmic contact strip line.

FIG. 6a illustrates an embodiment of the present invention, in which an n-type ohmic contact metal 60 is formed in a circular pattern with a diameter of approximately 100 microns at the center of a small chip with a size not more than 0.3×0.3 mm². FIG. 6b illustrates an embodiment corresponding to a larger chip, in which the n-type ohmic contact metal is formed in a circular pattern with a diameter of about 100 microns in 2×2 array. Depending on the size, the chip may be formed in 3×3 array or in 4×4 array.

FIGS. 7a and 7b show embodiments of electrode wiring lines used to form a single Au wiring bonding only. The n-type ohmic contact metal is formed in the shape of electrode wiring lines in various types having a width of several tens of microns. One wire bonding may be performed at the center of the n-type ohmic contact metal. Otherwise, if necessary, two or more wire bondings may be performed.

As described above, the n-type ohmic contact metal according to the present invention is not intended to embody a fine line width with a micrometer unit and a shadow masking process is sufficient. However, if an embodiment of the fine line width having a micrometer unit is required, the photolithographic process may be carried out. In other words, if the width of lead wire is greater than 50 microns, a shadow masking process is sufficient. The photolithography process is required only when the width of lead wire is less than 50 microns.

(9) Step of Surface Roughening of N-Type GaN Layer

If necessary, a step of surface roughening may be performed, after removing the sapphire substrate and before or after forming the ohmic contact electrode, in order to improve the light extraction efficiency.

In general, there are two approaches used to enhance the light emission efficiency of LEDs. The first is to increase the internal quantum efficiency, and the second is to increase the light extraction efficiency. The first approach of increasing the internal quantum efficiency is related with the quality of the crystal structure of an LED as well as to the structure of quantum well. Although the structure embodying high internal quantum efficiency has already been known, diverse researches are still in progress in that respect. However, this approach has not yet brought any additional improvement. On the other hand, the second approach of increasing the light extraction efficiency is to allow the light generated from the light emitting layer to be reflected to the exterior as much as possible. This approach still has a lot of room for improvement.

Since the refractive index of the GaN layer is generally about 2.5, a total reflection angle or a light escaping angle is approximately 37 degrees, considering a refractive index 1.5 of epoxy, which is a molding material. In other words, an incident light to the interface between the light emitting layer and the epoxy molding material at an angle greater than 37 degrees cannot escape to the exterior, but rather is trapped inside by continuously repeating the total reflection on the interface of the light emitting layer. An incident light with an angle less than 37 degrees only can escape outward. When ignoring the light generated from the side or rear surface of the light emitting layer, only about 10% of light is expected to successfully escape from the light emitting layer to the exterior. Accordingly, it is preferable to form the roughened surface of the n-type GaN layer in order to increase the total reflection angle, so that a large quantity of light can escape.

FIG. 8 shows the structure of an LED having an n-type GaN layer with a roughened surface. Referring to FIG. 8, if the surface of the n-type GaN layer is exposed after the removal of the sapphire substrate, the surface can be roughened so as to have the shape of polygonal cone thereon by means of a dry or wet etching treatment, before or after forming the n-type ohmic contact metal. The step of forming the roughened surface on the n-type GaN layer is preferably carried out after the step of forming the n-type ohmic contact metal. However, the surface roughening may be formed before the step of forming the n-type ohmic contact metal, if the n-ohmic contact metal may be damaged during the step of the surface roughening.

Herein, the wet etching treatment is performed by melting KOH into distilled water until its concentration reaches about 2 mole or less (0.1-2 mole), introducing a sample into the resultant solution, and irradiating an UV light source thereto. On the other hand, the dry etching treatment is performed by means of a plasma etching technique, which uses gas such as Cl₂, BCl₃, or the like.

It is preferable to form an additional metal layer by using the above-described materials having excellent resistance to the above treatment, because the metal layer exposed on the sub-mount surface may be damaged.

Additionally, the region of the n-type GaN layer, in which the n-type ohmic contact metal has not been formed, is coated with a mixture containing epoxy and a material (e.g. TiO₂ powder) having a refractive index of about 2.4, which is transparent under visible light and has a refractive index similar to that of GaN, to a thickness of less than a few microns, so as to induce an effect similar to the roughening of the surface. Finally, the resultant structure is covered with a molding material.

(10) Step of Dicing Sub-Mount Substrate

When at least two LED unit chips are formed on a single sub-mount substrate, the sub-mount substrate has to be diced so as to have a unit chip. If necessary, the sub-mount substrate may be diced so as to have at least one unit chip.

The sub-mount substrate is diced into a unit chip by means of dicing treatment, etc. The term “dicing” refers to a process of cutting a substrate with a circular rotating diamond wheel blade.

(11) Step of Bonding to Lead Frame

The sub-mount chip obtained from the preceding step may be attached to a lead frame.

The lead frame refers to a package for use in the manufacture of a finished LED lamp. Any LED packages other than lead frames may be used in the scope of the present invention.

In a variant, the unit chip separated from the sapphire substrate comprising the grown crystal structure of an LED, is not bonded to the sub-mount substrate but is bonded to a lead frame, before the removal of the sapphire substrate. This is also included in the scope of the present invention.

(12) Step of Wire Bonding

Wire bonding may be performed for electric connection of anode and cathode.

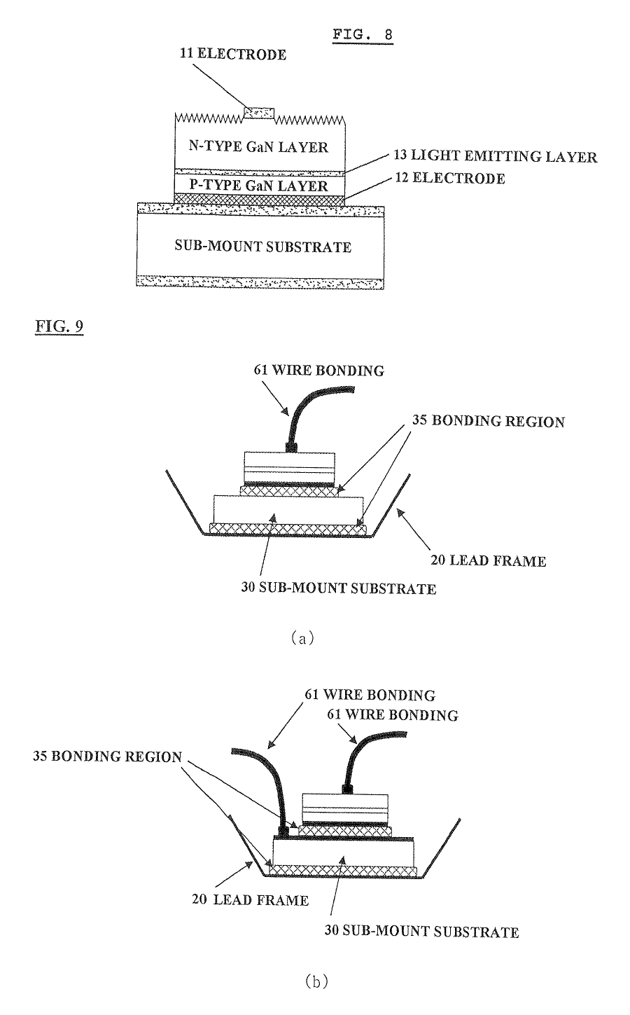

FIG. 9a is a schematic cross-sectional view of the LED device manufactured by using a metal substrate or a heavily doped silicon wafer as a sub-mount substrate 30 with excellent conductivity, and by removing the sapphire substrate. Herein, the metal sub-mount substrate 30 is spontaneously connected to the anode (p-type). Therefore, Au wire bonding 61 is connected to the cathode only. In this case, p-type electrode wire bonding is not required.

As described above, according to the present invention, at least two unit chips, spaced apart from each other, are bonded to the sub-mount substrate, and then the sub-mount substrate is cut in a position between two adjacent unit chips. Otherwise, only one unit chip is bonded to the sub-mount substrate having a size greater than the size of the region in which the unit chip is bonded. By doing so, it is possible to obtain a characteristic structure, wherein the surface of the sub-mount substrate extends from the circumference of the region in which the unit chip is bonded. In this case, such extended surface of the sub-mount substrate may be subjected to wire bonding. Therefore, a sub-mount substrate, whose conductivity is insufficient, may also be used. Additionally, because the heat dissipation area is larger than the area of the crystal structure, heat dissipation is improved.

FIG. 9b is a schematic cross-sectional view of the LED manufactured by using a silicon wafer or a ceramic substrate (e.g. AlN) as a sub-mount substrate 30. Since the sub-mount substrate has insufficient conductivity here, two Au wire bondings 61 are required for the connection of the anode and the cathode, respectively. Herein, a conductive metal layer is required on the surface of the sub-mount substrate for the connection of the anode. Particularly, in the case of a semiconductor sub-mount substrate such as a silicon wafer, an insulating layer is also required between the sub-mount substrate and a surface conductive metal layer for the isolation between sub-mount substrate and the anode or the cathode.

(13) Step of Forming Molding Portion

The LED structure obtained as described above is covered with a molding material such as epoxy or a molding material containing a phosphor to complete manufacture of the LED device. The molding material that may be used includes, but is not limited thereto, epoxy, silicone and acrylic resins.

Although the forgoing description exemplified the case of a high-output LED, the invention may be applicable to the case of a low-output LED. Additionally, the foregoing description exemplified an LED comprising the crystal structure of a GaN LED on a sapphire substrate. However, the forgoing embodiments are merely exemplary and are not to be misconstrued as limiting the present invention. The present teachings can be readily applied to other types of methods. The description of the present invention is intended to be illustrative, and not to limit the scope of the claims. Many alternatives, modifications, and variations will be apparent to those skilled in the art.

### INDUSTRIAL APPLICABILITY

As can be seen from the foregoing, the novel light emitting diode device according to the present invention has a characteristic structure, wherein the surface of a sub-mount substrate extends from the circumference of a region in which a unit chip is bonded. The extended surface of the sub-mount substrate may be subjected to wire bonding, or may serve to form a reflection layer that reflects the light emitted from the lateral surfaces of the LED, so that the light can be reflected to the exterior.

The above characteristic structure has never been disclosed in the prior art, and can be obtained only by the inventive process comprising the steps of: forming a unit chip from a sapphire wafer, on which the crystal structure of a GaN LED has been grown; bonding at least one unit chip to a sub-mount substrate in such a manner that two adjacent unit chips are spaced apart from each other; and removing the sapphire substrate by means of laser. Additionally, according to the above process, the sapphire wafer, on which the crystal structure of a GaN LED has grown, is split into a unit chip, before the removal of the sapphire substrate. Therefore, no crack occurs in the crystal structure, because the unit chip of the sapphire substrate, which has a size smaller than the region to be subjected to laser irradiation, is separated by one-shot of laser beams. As a result, the reduction of yield due to the crack of the crystal structure of an LED can be completely eliminated in comparison with the prior art.

1-17. (canceled)

18. A first preform for manufacturing a light emitting diode device that comprises a sapphire substrate, on which a crystal structure of a GaN light emitting diode has grown, mounted on a sub-mount substrate in the form of at least two unit chips.

19. The first preform for manufacturing a light emitting diode device according to claim 18, wherein a pattern that displays a position, in which the unit chip is bonded, or a pattern that displays a position, in which the sub-mount substrate is split into the unit chip, is formed on the sub-mount substrate.

20. The first preform for manufacturing a light emitting diode device according to claim 18, wherein at least two unit chips are bonded periodically to a single sub-mount substrate, while being spaced apart at a predetermined interval between two adjacent unit chips.

21. The first preform for manufacturing a light emitting diode device according to claim 18, wherein adjacent unit chips have an interval controlled to prevent each unit chip being placed over an edge of a region to be subjected to irradiation of laser beams, when removing the sapphire substrate with laser.

22. The first preform for manufacturing a light emitting diode device according to claim 18, wherein a metal layer is formed on the first surface of the sub-mount substrate having the sapphire substrate, on which a crystal structure of a GaN light emitting diode has grown, mounted in the form of unit chips.

23. A second preform for manufacturing a light emitting diode device, which is obtained from the first preform for manufacturing a light emitting diode device according to claims 18, which comprises a sapphire substrate, on which the crystal structure of a GaN light emitting diode has grown, mounted on a sub-mount substrate in the form of at least two unit chips, by removing the sapphire substrate.

24. A third preform for manufacturing a light emitting diode device, which is obtained from the first preform for manufacturing a light emitting diode device according to claim 18, which comprises a sapphire substrate, on which the crystal structure of a GaN light emitting diode has grown, mounted on a sub-mount substrate in the form of at least two unit chips, by removing the sapphire substrate, and then by cutting the sub-mount substrate in a position between two adjacent unit chips.

25. A method for manufacturing a light emitting diode device by allowing a crystal structure of a gallium nitride light emitting diode to grow on a sapphire substrate, which comprises the steps of:
splitting the sapphire substrate, on which the crystal structure of the light emitting diode has grown, into a unit chip; and
removing the sapphire substrate from the unit chip.

26. The method for manufacturing a light emitting diode according to claim 25, which further comprises, before the step of removing the sapphire substrate, a step of bonding at least one unit chip to a sub-mount substrate after splitting the sapphire substrate, on which the crystal structure of the light emitting diode has grown, into a unit chip.

27. The method for manufacturing a light emitting diode according to claim 26, wherein at least two unit chips are bonded to the sub-mount substrate in the unit chip bonding step, and the method further comprises a step of cutting the sub-mount substrate in such a manner that the sub-mount substrate has at least one unit chip, after the step of removing the sapphire substrate.

28. The method for manufacturing a light emitting diode according to claim 27, wherein at least two unit chips, bonded to a single sub-mount substrate, are arranged periodically, while being spaced apart at a predetermined interval between adjacent two unit chips, when bonding at least two unit chips to the sub-mount substrate.

29. The method for manufacturing a light emitting diode according to claim 25, wherein the sapphire substrate is removed by way of laser in the step of removing the sapphire substrate.

30. The method for manufacturing a light emitting diode according to claim 26, wherein at least one unit chip is bonded to the sub-mount substrate in such a manner that adjacent unit chips have a interval controlled to prevent each unit chip being placed over an edge of a region to be subjected to irradiation of laser beams, when removing the sapphire substrate with laser.

31. The method for manufacturing a light emitting diode according to claim 29, wherein the laser has a wavelength ranging from 200 nm to 365 nm.

32. The method for manufacturing a light emitting diode according to claim 25, wherein the crystal structure of the light emitting diode is allowed to grow on the sapphire substrate having a metal buffer layer formed thereon, and the sapphire substrate is removed by dissolving the metal buffer layer in the step of removing the sapphire substrate.

33. The method for manufacturing a light emitting diode according to claim 26, wherein at least two unit chips, spaced apart from each other at a predetermined interval, are bonded to the sub-mount substrate, and the sub-mount substrate is cut in a position between two adjacent unit chips, or only one unit chip is bonded to a sub-mount substrate larger than the surface area of the region in which the unit chip is bonded, and a surface of the sub-mount substrate extending from the circumference of the region, in which the unit chip is bonded, is subjected to wire bonding.

34. The method for manufacturing a light emitting diode according to claim 26, wherein at least one unit chip is bonded to the sub-mount substrate having a metal layer formed thereon.
